(19) United States
(12) Patent Application Publication
(10) Pub. No.: US 2026/0282703 A1
(43) Pub. Date: Sep. 17, 2026

(54) DISPLAY DEVICE, METHOD OF MANUFACTURING DISPLAY DEVICE, AND ELECTRONIC DEVICE INCLUDING DISPLAY DEVICE

(71) Applicant: SAMSUNG DISPLAY CO., LTD., YONGIN-SI (KR)

(72) Inventors: JOONGEOL KIM, Yongin-si (KR); JIN-WON LEE, Yongin-si (KR)

(21) Appl. No.: 19/558,817

(22) Filed: Mar. 6, 2026

(30) Foreign Application Priority Data
Mar. 14, 2025 (KR) 10-2025-0033436

(51) Int. Cl. H10K 59/80; H10K 59/12; H10K 59/35; H10K 102/00

(52) U.S. Cl. CPC H10K 59/80517; H10K 59/1201; H10K 59/35; H10K 2102/351

(57) ABSTRACT

A method of manufacturing a display device includes forming a metal laminate by sequentially stacking a first metal layer, a second metal layer, and a third metal layer on a substrate, performing a first etching process on the metal laminate after forming a first photoresist pattern on the metal laminate, ashing the first photoresist pattern after performing the first etching process, performing a second etching process on the metal laminate using the ashed first photoresist pattern, and forming a first pixel electrode of the first sub-pixel, a second pixel electrode of the second sub-pixel, and a third pixel electrode of a third sub-pixel by removing the first photoresist pattern. Forming a second photoresist pattern. Performing a third etching process on the metal laminate. The first pixel electrode, the second pixel electrode, and the third pixel electrode are formed to have different thicknesses from each other.

### CROSS-REFERENCE TO RELATED APPLICATION

This application claims priority under 35 USC §119 to Korean Patent Application No. 10-2025-0033436, filed on March 14, 2025 in the Korean Intellectual Property Office, the present disclosure of which is incorporated by reference in its entirety herein.

### 1. Technical Field

One or more embodiments relate to a display device, a method of manufacturing the display device, and an electronic device including the display device.

### 2. Discussion of Related Art

An increasing number of lightweight and compact flat panel display devices are being developed along with the advancement of the information society. Flat panel display devices include liquid crystal displays (LCDs), field emission displays (FEDs), plasma display panels (PDPs), organic light emitting diode (OLED) displays, and the like.

Among those flat panel display devices, organic light-emitting diode (OLED) displays output images using organic light-emitting diodes, which emit light through the recombination of electrons and holes. OLED displays are receiving attention as next-generation displays by virtue of fast response speed and operation with low power consumption.

### SUMMARY

One or more embodiments provide a display device having increased resolution and emission characteristics, and an electronic device including the same.

The problems to be solved by the present disclosure are not limited to the problems mentioned above, and other problems and advantages of embodiments of the present disclosure that are not mentioned will be understood by the following description and will be more clearly understood by the described embodiments of the present disclosure.

According to an embodiment of the present disclosure, a method of manufacturing a display device includes forming a metal laminate by sequentially stacking a first metal layer, a second metal layer, and a third metal layer on a substrate. The metal laminate including regions corresponding to a first sub-pixel, a second sub-pixel and a third sub-pixel. A first photoresist pattern is formed in the regions corresponding to the first sub-pixel and the second sub-pixel. A first etching process is then performed on the metal laminate. The first photoresist pattern is not formed in the region corresponding to the third sub-pixel. The first photoresist pattern is ashed after performing the first etching process to form an ashed first photoresist pattern. A second etching process is performed on the metal laminate which has been etched by the first etching process using the ashed first photoresist patter. A first pixel electrode of the first sub-pixel, a second pixel electrode of the second sub-pixel, and a third pixel electrode of a third sub-pixel is formed by removing the ashed first photoresist pattern. A second photoresist pattern is formed in the region corresponding to the first sub-pixel, the region corresponding to the second sub-pixel, and a region corresponding to the third sub-pixel. A third etching process is then performed on the metal laminate which has been etched by the second etching process. The first pixel electrode, the second pixel electrode, and the third pixel electrode are formed to have different thicknesses from each other.

In an embodiment, the thickness of the first pixel electrode may be thicker than the thickness of the second pixel electrode, and the thickness of the second pixel electrode may be thicker than the thickness of the third pixel electrode.

In an embodiment, a first separation distance between the first pixel electrode and the second pixel electrode may be equal to a second separation distance between the second pixel electrode and the third pixel electrode. A third separation distance between the third pixel electrode and the first pixel electrode is equal to the first and second separation distances.

In an embodiment, a thickness of the first photoresist pattern in the region corresponding to the first sub-pixel may be thicker than a thickness of the first photoresist pattern in the region corresponding to the second sub-pixel.

In an embodiment, the third metal layers of the first pixel electrode, the second pixel electrode, and the third pixel electrode may have different thicknesses from each other.

In an embodiment, the first metal layer and the second metal layer of each of the first pixel electrode, the second pixel electrode, and the third pixel electrode may have a same thickness as each other.

In an embodiment, during the first etching process of the metal laminate, the third metal layer in the region corresponding to the third sub-pixel may be etched.

In an embodiment, after the first etching process of the metal laminate is performed, a thickness of the third metal layer overlapping the first sub-pixel may be equal to a thickness of the third metal layer overlapping the second sub-pixel.

In an embodiment, after the first etching process of the metal laminate is performed, the thickness of the third metal layer overlapping the first sub-pixel may be thicker than a thickness of the third metal layer overlapping the third sub-pixel.

In an embodiment, during the ashing of the first photoresist pattern, a thickness of the first photoresist pattern in the region overlapping the first sub-pixel may decrease, and the first photoresist pattern in the region overlapping the second sub-pixel may be removed.

In an embodiment, during the second etching process of the metal laminate, the third metal layer in the region corresponding to the third sub-pixel may further be etched.

In an embodiment, after the second etching process of the metal laminate is performed, a thickness of the third metal layer in the region corresponding to the second sub-pixel may be thicker than a thickness of the third metal layer in the region corresponding to the third sub-pixel.

In an embodiment, the third etching process of the metal laminate may be performed by wet etching.

In an embodiment, a surface of the third metal layer in the region corresponding to the first sub-pixel may not be etched during the first to third etching processes.

In an embodiment, the first sub-pixel may emit red light, the second sub-pixel may emit blue light, and the third sub-pixel may emit green light.

According to an embodiment of the present disclosure, a display device includes a substrate including regions corresponding to a first sub-pixel, a second sub-pixel, and a third sub-pixel, respectively. A first pixel electrode, a second pixel electrode, and a third pixel electrode are arranged on the substrate, and located in the region corresponding to the first sub-pixel, the region corresponding to the second sub-pixel, and the region corresponding to the third sub-pixel, respectively. The first pixel electrode, the second pixel electrode, and the third pixel electrode each include a first metal layer, a second metal layer, and a third metal layer sequentially stacked. The third metal layers of the first pixel electrode, the second pixel electrode, and the third pixel electrode have different thicknesses from each other. A roughness of a surface of the third metal layer of the first pixel electrode is less than roughness of a surface of the third metal layer of the second pixel electrode.

In an embodiment, a first separation distance between the first pixel electrode and the second pixel electrode may be equal to a second separation distance between the second pixel electrode and the third pixel electrode. A third separation distance between the third pixel electrode and the first pixel electrode is equal to the first and second separation distances.

In an embodiment, the thickness of the third metal layer of the first pixel electrode may be thicker than the thickness of the third metal layer of the second pixel electrode, and the thickness of the third metal layer of the second pixel electrode may be thicker than the thickness of the third metal layer of the third pixel electrode.

In an embodiment, the first sub-pixel may emit red light, the second sub-pixel may emit blue light, and the third sub-pixel may emit green light.

According to an embodiment of the present disclosure, an electronic device includes a memory in which at least one program is stored, a processor configured to operate by executing the at least one program, a display device configured to provide visual information by receiving data from the processor, and a power module configured to supply power to the display device. The display device includes a substrate including regions corresponding to a first sub-pixel, a second sub-pixel, and a third sub-pixel, respectively, and a first pixel electrode, a second pixel electrode, and a third pixel electrode arranged on the substrate, and located in the region corresponding to the first sub-pixel, the region corresponding to the second sub-pixel, and the region corresponding to the third sub-pixel, respectively. The first pixel electrode, the second pixel electrode, and the third pixel electrode each include a first metal layer, a second metal layer, and a third metal layer sequentially stacked. The third metal layers of the first pixel electrode, the second pixel electrode, and the third pixel electrode have different thicknesses from each other. A roughness of a surface of the third metal layer of the first pixel electrode is less than a roughness of a surface of the third metal layer of the second pixel electrode.

### BRIEF DESCRIPTION OF THE DRAWINGS

The following drawings attached to this specification illustrate non-limiting embodiments of the present disclosure and, together with the detailed description of the present disclosure described below, serve to further understand the technical idea of the present disclosure; therefore, the present disclosure should not be interpreted as being limited to matters described in such drawings:

FIG. 1 is a schematic plan view of an example of a display device according to an embodiment of the present disclosure;

FIG. 2 is a schematic perspective view of a bent shape of the display device of FIG. 1 according to an embodiment of the present disclosure;

FIG. 3 is a schematic block diagram of a structure of the display device of FIG. 1 according to an embodiment of the present disclosure;

FIG. 4 is a schematic diagram of an equivalent circuit of a sub-pixel of the display device of FIG. 1 according to an embodiment of the present disclosure;

FIG. 5 is a schematic cross-sectional view of an example of a cross-section taken along line A-A’ of FIG. 1 according to an embodiment of the present disclosure;

FIGS. 6 to 11 are schematic cross-sectional views of an example of a method of manufacturing a first pixel electrode, a second pixel electrode, and a third pixel electrode according to embodiments of the present disclosure;

FIG. 12 is a schematic plan view of an example of arranging a first sub-pixel, a second sub-pixel, and a third sub-pixel according to an embodiment of the present disclosure;

FIG. 13 is a block diagram of an electronic device according to an embodiment of the present disclosure; and

FIG. 14 is a variety of schematic diagrams of electronic devices according to various embodiments of the present disclosure.

### DETAILED DESCRIPTION OF EMBODIMENTS

As the present disclosure allows for various changes and numerous embodiments, certain non-limiting embodiments will be illustrated in the drawings and described in detail in the written description. Effects and features of the present disclosure, and methods of achieving them will be clarified with reference to non-limiting embodiments described below in detail with reference to the drawings. The present disclosure may, however, be embodied in many different forms and should not be construed as being limited to the embodiments set forth herein.

In the following embodiments, the terms ʺfirst,ʺ ʺsecond,ʺ and the like are not used in a restrictive sense and are used to distinguish one element from another.

The singular forms as used herein are intended to include the plural forms as well unless the context clearly indicates otherwise.

It will be further understood that the terms "include" and/or "comprise" used herein specify the presence of stated features or elements, but do not preclude the presence or addition of one or more other features or elements.

In the following embodiments, it will be understood that, when a portion such as film, region, or element is referred to as being ʺonʺ another portion, this may include not only a case where the portion is directly on the other portion, but also a case where intervening films, regions, or elements may be present therebetween. When a portion such as film, region, or element is referred to as being ʺdirectly onʺ another portion, no intervening elements may be present.

Sizes of elements in the drawings may be exaggerated or reduced for convenience of explanation. For example, since sizes and/or thicknesses of elements in the drawings may be arbitrarily illustrated for convenience of explanation, embodiments of the present disclosure are not necessarily limited thereto.

Hereinafter, embodiments will be described in detail with reference to the accompanying drawings. Upon describing embodiments with reference to the accompanying drawings, the same or corresponding elements are denoted by the same reference numerals.

The present disclosure concerns a display device and method of manufacturing a display device in which a metal laminate includes first to third metal layers sequentially stacked. The third metal layers of a first pixel electrode of a first sub-pixel, a second pixel electrode of a second sub-pixel, and a third pixel electrode of a third sub-pixel may have different thicknesses from each other. Therefore, a different resonance structure may be implemented for each sub-pixel thereby increasing light efficiency while providing high resolution.

In the method of manufacturing the display device, the third metal layer of the first pixel electrode located in the region corresponding to the first sub-pixel may not be etched during each of a first etching process, a second etching process, and a third etching process. Accordingly, the third metal layer of the first pixel electrode may have minimal surface roughness thereby increasing emission uniformity of the first pixel electrode.

The third metal layer of the second pixel electrode located in the region corresponding to the second sub-pixel may be masked with a first photomask pattern during the first etching process but may be etched during the second etching process. The third metal layer of the second pixel electrode located in the region corresponding to the third sub-pixel may not be masked during the first and second etching processes and may be etched during these processes.

The third metal layer overlapping the second sub-pixel may be etched by the second etching process after an ashing process of the first photoresist pattern is performed, so that roughness of the surface due to the ashing process may be removed to increase emission uniformity of the second sub-pixel.

The first metal layer and the second metal layer may be etched once during the third etching process of the metal laminate. Therefore, separation distances between adjacent pixel electrodes of the first pixel electrode, the second pixel electrode and the third pixel electrode may be minimized.

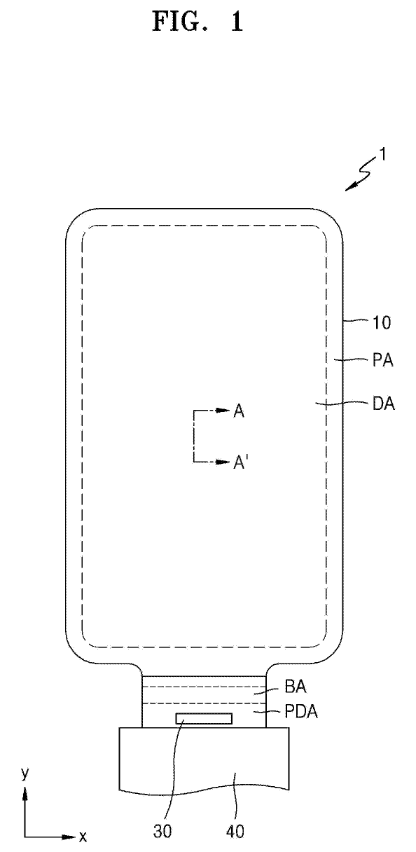

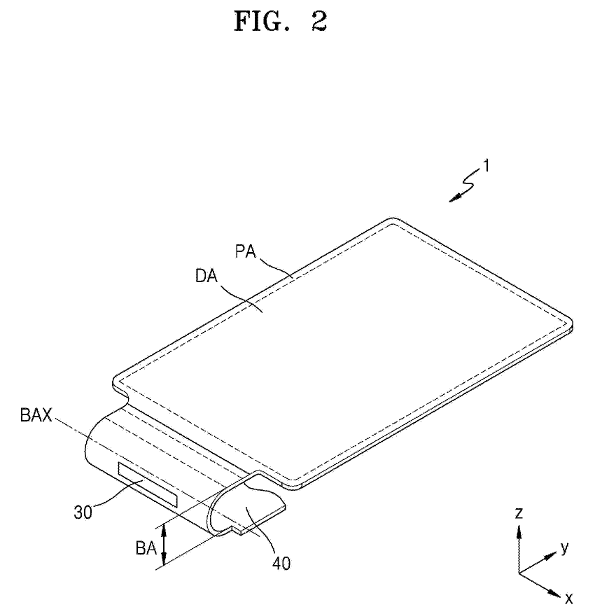

FIG. 1 is a schematic plan view of an example of a display device according to an embodiment, and FIG. 2 is a schematic perspective view of a bent shape of the display device of FIG. 1.

In this specification, a 'first direction x' may be a direction parallel to a width direction of a display device 1 or a bending axis BAX to be described later. A 'second direction y' may be a longitudinal direction of the display device 1, and a 'third direction z' may be interpreted as a stacking direction of components of the display device 1 to be described later or a direction perpendicular to both the first direction x and the second direction y. The first direction x, the second direction y, and the third direction z may be directions perpendicular to one another. However, embodiments of the present disclosure are not necessarily limited thereto, and the first direction x, second direction y, and third direction z may intersect each other at various different angles.

Referring to FIGS. 1 and 2, the display device 1 may be a device that displays at least one moving image and/or still image, and may display a screen on a display panel 10 or perform input and output of data. In an embodiment, the display device 1 may be used as a display screen of various electronic devices, such as televisions, laptops, monitors, billboards, and Internet of things (IoT) devices, as well as portable electronic devices, such as mobile phones, smartphones, tablet personal computers (PCs), mobile communication terminals, electronic organizers, e-books, portable multimedia players (PMPs), navigation systems, and ultra mobile PCs (UMPCs). The display device 1 according to an embodiment may also be applied to electronic devices, such as wearable devices, for example, smart watches, watch phones, glasses-type displays, and head mounted displays (HMDs). The display device 1 according to an embodiment may also be used as a display of various electronic devices, for example, dashboards of automobiles, center information displays (CIDs) on the center fascia or dashboards of automobiles, room mirror displays replacing side mirrors of automobiles, and displays on the rear surfaces of front seats to serve as entertainment devices for backseat passengers of automobiles. However, embodiments of the present disclosure are not necessarily limited thereto and the display device 1 may be applied to various other small-sized, medium-sized or large-sized electronic devices.

The display device 1 according to an embodiment may include a display area DA in which a plurality of pixels is positioned, and a peripheral area PA positioned outside the display area DA (e.g., in a plan view). The peripheral area PA may include a pad area PDA as an area, which is located on one side of the display area DA and in which various electronic components, such as an integrated circuit 30, or a flexible circuit board 40, are electrically attached, and a bending area BA between the display area DA and the pad area PDA. For example, in an embodiment shown in FIG. 1, the pad area PDA may be positioned on a lower side of the display area DA in the -y direction. However, embodiments of the present disclosure are not necessarily limited thereto. The display area DA, the peripheral area PA, the pad area PDA, and the bending area BA may be divided (e.g., spaced apart in plan view) on a substrate.

In some embodiments, FIG. 1 is a plan view of the shape of a substrate, and the like during the manufacturing process of the display device 1, and the substrate and the like, as illustrated in FIG. 2, may be bent in the bending area BA based on a bending axis BAX that extends in the first direction x. The bending direction may be set so that the pad area PDA is located behind the display area DA (e.g., in the -z direction). Accordingly, a size of the peripheral area PA that is perceived by a user may be minimized.

A circuit cover may be attached to the integrated circuit 30 and the flexible circuit board 40 of the pad area PDA. The circuit cover may protect the integrated circuit 30 and the flexible circuit board 40 from mechanical impacts and further provide waterproofing and insulation performance to the integrated circuit 30 and the flexible circuit board 40.

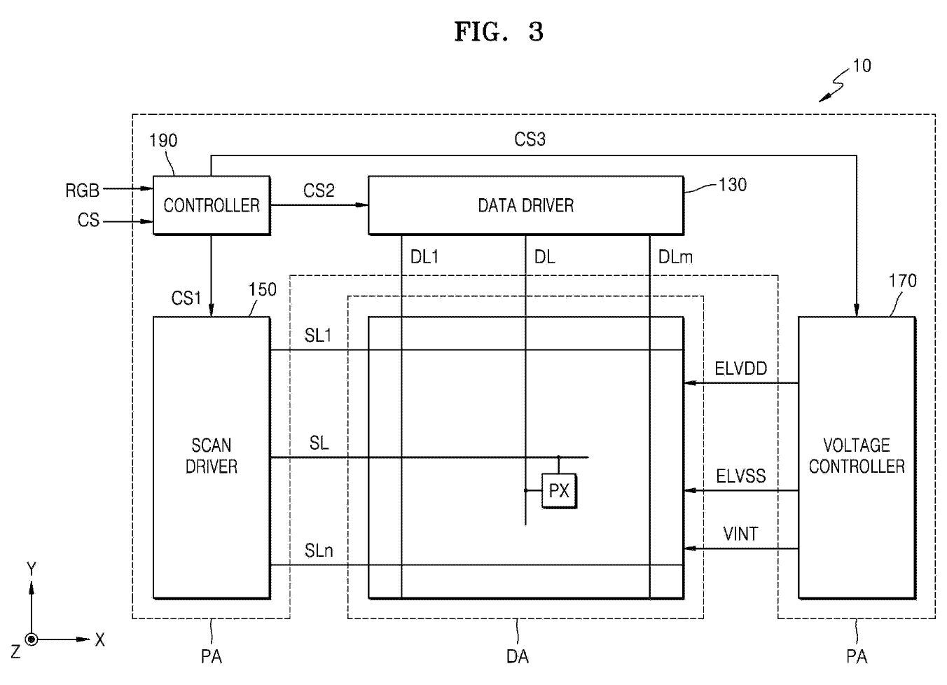

FIG. 3 is a schematic block diagram of a structure of the display device of FIG. 1.

Referring to FIG. 3, a plurality of scan lines SL1, ..., SLn extending along the first direction x, a plurality of data lines DL1, ..., DLm extending along the second direction y perpendicular to the first direction x, and a plurality of sub-pixels PX may be located in the display area DA. Here, m and n denote natural numbers greater than or equal to 3.

Wirings, along which electrical signals may be applied to the plurality of sub-pixels PX, may include the plurality of scan lines SL1, ..., SLn and the plurality of data lines DL1, ..., DLm. The plurality of scan lines SL1, ..., SLn, for example, may be arranged in a plurality of rows extending in the first direction x, to transmit scan signals to the sub-pixels PX. The plurality of data lines DL1, ..., DLm, for example, may be arranged in a plurality of columns extending in the second direction y, to transmit data signals to the sub-pixels PX. The plurality of sub-pixels PX may be positioned at portions where the plurality of scan lines SL1, ..., SLn and the plurality of data lines DL1, ..., DLm cross each other.

In an embodiment, the sub-pixels P may each include an emission element which emits red light, green light, blue light, or white light. For example, each sub-pixel PX may include an organic light-emitting diode OLED as an emission element, but is not necessarily limited thereto.

A data driver 130 may be arranged in the peripheral area PA for applying data signals to the display area DA, a scan driver 150 for applying scan signals to the display area DA, a voltage controller 170 for controlling voltages applied to the display area DA, and a controller 190 that may control the data driver 130, the scan driver 150, and the voltage controller 170.

The voltage controller 170 may generate and control a first voltage ELVDD, a second voltage ELVSS, and an initialization voltage VINT which are applied to the display area DA.

The first voltage ELVDD, the second voltage ELVSS, and the initialization voltage VINT may be applied to the plurality of sub-pixels PX. For example, in an embodiment the first voltage ELVDD may be a positive voltage, and the second voltage ELVSS may be a negative voltage or a ground voltage. In some examples, the second voltage ELVSS may have a lower level than the first voltage ELVDD.

The controller 190 may receive image signals RGB and a control signal CS from the exterior (e.g., a system board). The controller 190 may generate image data DATA by converting a data format of the image signals RGB to be appropriate for an interface between the data driver 130 and the controller 190. The controller 190 may apply the image data DATA having the converted data format to the data driver 130.

In an embodiment, the controller 190 may generate and output a first control signal CS1, a second control signal CS2, and a third control signal CS3, in response to the control signal CS applied from the exterior (e.g., an external device, etc.). The first control signal CS1 may be defined as a scan control signal and the second control signal CS2 may be defined as a data control signal. The first control signal CS1 may be applied to the scan driver 150. The second control signal CS2 may be applied to the data driver 130, and the third control signal CS3 may be applied to the voltage controller 170.

The scan driver 150 may generate a plurality of scan signals, in response to the first control signal CS1. The plurality of scan signals may be applied to the plurality of sub-pixels PX through the plurality of scan lines SL1, ..., SLn.

The data driver 130 may generate a plurality of data voltages corresponding to the image data DATA, in response to the second control signal CS2. The plurality of data voltages may be applied to the plurality of sub-pixels PX through the plurality of data lines DL1, ..., DLm. The data driver 130 may simultaneously apply the data voltages, which are generated in units of sub-pixel rows, to the plurality of sub-pixels PX through the plurality of data lines DL1, ..., DLm.

The plurality of sub-pixels PX may receive the plurality of data voltages, in response to the plurality of scan signals. The plurality of sub-pixels PX may display an image by emitting light of brightness corresponding to the plurality of data voltages. The plurality of sub-pixels PX may display the image by emitting light sequentially or simultaneously.

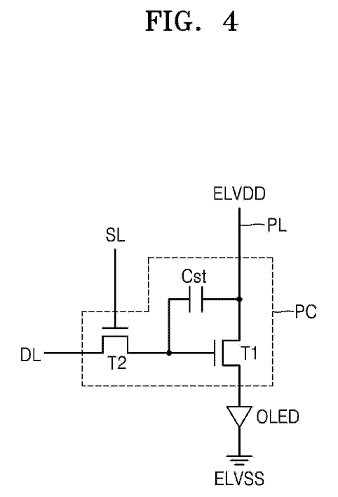

FIG. 4 is a schematic diagram of an equivalent circuit of a sub-pixel of the display device of FIG. 1.

Referring to FIG. 4, a pixel circuit PC may be connected to a display element, for example, an organic light-emitting diode OLED. The pixel circuit PC may be located in the display area DA. In an embodiment, the pixel circuit PC may include a driving thin-film transistor T1, a switching thin-film transistor T2, and a storage capacitor Cst. However, embodiments of the present disclosure are not necessarily limited thereto and the number of the transistors and capacitors of the pixel circuit PC may vary. In an embodiment, the organic light-emitting diode OLED may emit red, green, or blue light, or may emit red, green, blue, or white light.

The switching thin-film transistor T2 may be connected to a scan line SL and a data line DL, and may transmit a data signal or data voltage, which is input from the data line DL, to the driving thin-film transistor T1 based on a scan signal or switching voltage input from the scan line SL. The storage capacitor Cst may be connected to the switching thin-film transistor T2 and a driving voltage line PL, and may store a voltage corresponding to a difference between a voltage transmitted from the switching thin-film transistor T2 and a first voltage ELVDD applied to the driving voltage line PL.

The driving thin-film transistor T1 may be connected to the driving voltage line PL and the storage capacitor Cst, and may control a driving current, which flows in the organic light-emitting diode OLED from the driving voltage line PL, in response to a voltage value stored in the storage capacitor Cst. The organic light-emitting diode OLED may emit light with a certain brightness depending on the level of the driving current. A counter electrode of the organic light-emitting diode OLED may receive a second voltage ELVSS.

Although FIG. 4 illustrates that the pixel circuit PC includes two thin-film transistors and one storage capacitor. In some embodiments the pixel circuit PC may include at least three, four, or five thin-film transistors, and may include at least two or three capacitors.

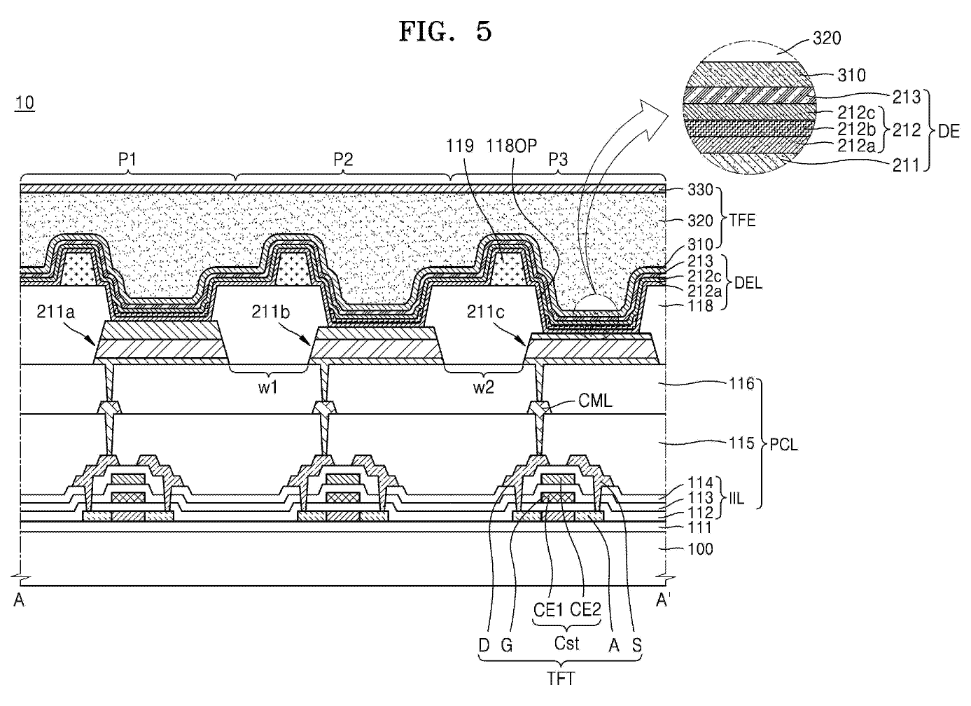

FIG. 5 is a schematic cross-sectional view of an example of a cross-section taken along line A-A' of FIG. 1.

Referring to FIG. 5, the display device 1 may include a display panel 10. In an embodiment, the display panel 10 may include a substrate 100, a buffer layer 111, a pixel circuit layer PCL, a display element layer DEL, and a thin-film encapsulation layer TFE.

In an embodiment, the substrate 100 may include a transparent glass material mainly containing SiO2. However, embodiments of the present disclosure are not necessarily limited thereto, and the substrate 100 may also include a transparent plastic material. In an embodiment, the plastic material may include polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), cellulose acetate propionate (CAP), or the like. In an embodiment, the substrate 100 may have a multilayer structure including a base layer and a barrier layer that include the aforementioned polymer resin. The substrate 100 including the polymer resin may have flexible, rollable, and bendable characteristics.

The buffer layer 111 may be arranged on the substrate 100 (e.g., disposed directly thereon in the z direction). In an embodiment, the buffer layer 111 may include an inorganic insulating material, such as silicon nitride, silicon oxynitride, and silicon oxide, and may be a single layer or multilayer including the aforementioned inorganic insulating material.

The pixel circuit layer PCL may be arranged on the buffer layer 111 (e.g., disposed directly thereon in the z direction). The pixel circuit layer PCL may include an inorganic insulating layer IIL, a first planarization layer 115, and a second planarization layer 116 that are arranged below or/and above a thin-film transistor TFT included in the pixel circuit PC and components of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polysilicon. Alternatively, the semiconductor layer A may include amorphous silicon, an oxide semiconductor, or an organic semiconductor. The semiconductor layer A may include a channel region, and a drain region and a source region arranged on opposite sides of the channel region, respectively (e.g., in a plan view). A gate electrode G may overlap the channel region (e.g., in the z direction).

The gate electrode G may include a low-resistance metal material. In an embodiment, the gate electrode G may include a conductive material including molybdenum (Mo), aluminum (Al), copper (Cu), titanium (Ti), or the like, and may be formed as a multilayer or single layer including the material.

In an embodiment, the first gate insulating layer 112 between the semiconductor layer A and the gate electrode G (e.g., in the z direction) may include an inorganic insulating material, such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), or zinc oxide (ZnOX). The zinc oxide (ZnOX) may be zinc oxide (ZnO) and/or zinc peroxide (ZnO2).

The second gate insulating layer 113 may cover the gate electrode G. In an embodiment, the second gate insulating layer 113, like the first gate insulating layer 112, may include an inorganic insulating material, such as silicon oxide (SiO₂), silicon nitride (SiNX), silicon oxynitride (SiON), aluminum oxide (Al2O₃), titanium oxide (TiO₂), tantalum oxide (Ta2O₅), hafnium oxide (HfO₂), or zinc oxide (ZnOₓ). The zinc oxide (ZnO_{X}) may be zinc oxide (ZnO) and/or zinc peroxide (ZnO₂).

An upper electrode CE2 of the storage capacitor Cst may be arranged on the second gate insulating layer 113 (e.g., disposed directly thereon in the z direction). The upper electrode CE2 may overlap the gate electrode G that is located below the upper electrode CE2 (e.g., in the z direction). In an embodiment, the gate electrode G and the upper electrode CE2 that overlap each other with the second gate insulating layer 113 arranged between the gate electrode G and the upper electrode CE2 may form the storage capacitor Cst of the pixel circuit PC. For example, the gate electrode G may function as a lower electrode CE1 of the storage capacitor Cst. In this way, the storage capacitor Cst and the thin-film transistor TFT may be formed to overlap each other. However, embodiments of the present disclosure are not necessarily limited thereto, and in some embodiments, the storage capacitor Cst may be formed not to overlap the thin-film transistor TFT.

In an embodiment, the upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer of the aforementioned material.

The interlayer insulating layer 114 may cover the upper electrode CE2. In an embodiment, the interlayer insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZₙOₓ). The zinc oxide (ZₙO_{X}) may be zinc oxide (ZₙO) and/or zinc peroxide (ZₙO₂). The interlayer insulating layer 114 may be a single layer or multilayer including the aforementioned inorganic insulating material.

A drain electrode D and a source electrode S may each be located on the interlayer insulating layer 114. The drain electrode D and the source electrode S may include a material having good conductivity. In an embodiment, the drain electrode D and the source electrode S may include a conductive material including molybdenum (Mo), aluminum (Al), copper (Cu), titanium (Ti), or the like, and may be formed as a multilayer or single layer including the material. For example, in an embodiment, the drain electrode D and the source electrode S may have a multilayer structure of Ti/Al/Ti.

The first planarization layer 115 may be arranged to cover the drain electrode D and the source electrode S. The first planarization layer 115 may include an organic insulating layer. In an embodiment, the first planarization layer 115 may include an organic insulating layer, for example a general-purpose polymer, such as polymethylmethacrylate (PMMA) or polystyrene (PS), a polymer derivative having a phenol group, an acrylic polymer, an imide polymer, an aryl ether polymer, an amide-based polymer, a fluorinated polymer, a p-xylene polymer, a vinyl alcohol polymer, and a blend thereof.

A connection electrode CML may be arranged on the first planarization layer 115 (e.g., disposed directly thereon in the z direction). The connection electrode CML may be connected to the drain electrode D or the source electrode S through a contact hole of the first planarization layer 115. The connection electrode CML may include a material with good conductivity. In an embodiment, the connection electrode CML may include a conductive material including molybdenum (Mo), aluminum (Al), copper (Cu), titanium (Ti), or the like, and may be formed as a multilayer or single layer including the material. In an embodiment, the connection electrode CML may have a multilayer structure of Ti/Al/Ti.

The second planarization layer 116 may be arranged to cover the connection electrode CML. The second planarization layer 116 may include an organic insulating layer. In an embodiment, the second planarization layer 116 may include an organic insulating layer, for example, a general-purpose polymer, such as polymethylmethacrylate (PMMA) or polystyrene (PS), a polymer derivative having a phenol group, an acrylic polymer, an imide polymer, an aryl ether polymer, an amide-based polymer, a fluorinated polymer, a p-xylene polymer, a vinyl alcohol polymer, and a blend thereof.

The display element layer DEL may be arranged on the pixel circuit layer PCL (e.g., disposed directly thereon in the z direction). The display element layer DEL may include a display element DE. The display element DE may be an organic light-emitting diode OLED. In an embodiment, a pixel electrode 211 of the display element DE may be electrically connected to the connection electrode CML through a contact hole of the second planarization layer 116.

In an embodiment, the pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 211 may further include a film that includes ITO, IZO, ZnO, or In₂O₃ and is located above/below the reflective film.

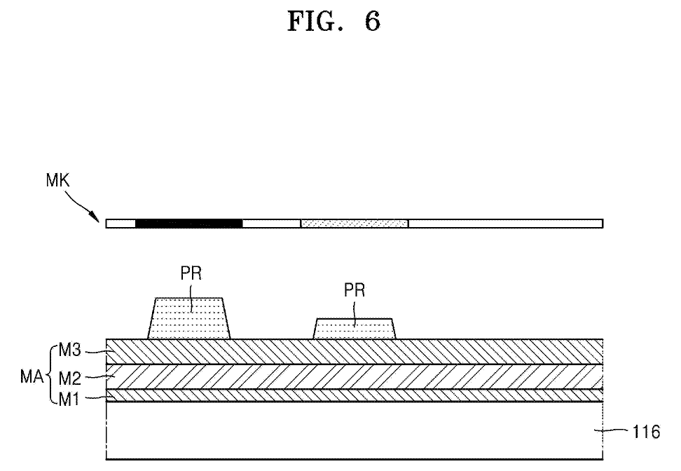

In some embodiments, the pixel electrode 211 according to embodiments may have a thickness (e.g., length in the z direction) different for each sub-pixel P1, P2, and P3. This will be described in detail later with reference to FIG. 6 and subsequent drawings.

A pixel defining layer 118 including an opening 118OP, through which a central portion of the pixel electrode 211 is exposed, may be arranged on the pixel electrode 211. The pixel defining layer 118 may include an organic insulating material and/or an inorganic insulating material. The opening 118OP may define an emission area EA of light emitted from the display element DE (hereinafter, referred to as an emission area of the display element DE). For example, a width of the opening 118OP (e.g., in a plan view) may correspond to a width of the emission area EA of the display element DE (e.g., in a plan view).

In an embodiment, the pixel defining layer 118 may include a light-shielding material and may be formed as a black layer. In an embodiment, the light-shielding material may include resin or paste containing carbon black, carbon nanotubes, or black dye, metal particles, for example, nickel, aluminum, molybdenum, and alloys thereof, metal oxide particles (e.g., chromium oxide), or metal nitride particles (e.g., chromium nitride). In case that the pixel defining layer 118 includes a light-shielding material, external reflections due to metal structures arranged below the pixel defining layer 118 may be reduced.

A spacer 119 may be arranged on the pixel defining layer 118 (e.g., disposed directly thereon in the z-axis direction). The spacer 119 may be arranged to suppress damage to the substrate 100 in a method of manufacturing the display device. A mask sheet may be used in case of manufacturing the display panel 10. The mask sheet may enter the opening 118OP of the pixel defining layer 118 or may be in close contact with the pixel defining layer 118, thereby suppressing a defect that a portion of the substrate 100 is damaged or broken upon depositing a deposition material on the substrate 100.

In an embodiment, the spacer 119 may include an organic insulating material, such as polyimide. Alternatively, in an embodiment the spacer 119 may include an inorganic insulating material, such as silicon nitride or silicon oxide, or may include an organic insulating material and an inorganic insulating material.

In an embodiment, the spacer 119 may include a different material from the pixel defining layer 118. However, embodiments of the present disclosure are not necessarily limited thereto. For example, in an embodiment, the spacer 119 may include the same material as the pixel defining layer 118. In this case, the pixel defining layer 118 and the spacer 119 may be formed together during a mask process using a halftone mask or the like.

An intermediate layer 212 may be arranged on the pixel defining layer 118 (e.g., in the z direction). The intermediate layer 212 may include an emission layer 212b arranged in the opening 118OP of the pixel defining layer 118. The emission layer 212b may include a high-molecular or low-molecular organic material that emits light of a certain color.

A first functional layer 212a and a second functional layer 212c may be arranged above and below the emission layer 212b, respectively (e.g., in the z direction). The first functional layer 212a, for example, may include a hole transport layer (HTL) or may include the hole transport layer and a hole injection layer (HIL). The second functional layer 212c may be a component located on the emission layer 212b and may be optional. The second functional layer 212c may include an electron transport layer (ETL) and/or an electron injection layer (EIL). In an embodiment, the first functional layer 212a and/or the second functional layer 212c may be common layers formed to cover the entire substrate 100, similar to a counter electrode 213 to be described later.

A counter electrode 213 may include a conductive material having a relatively low work function. For example, in an embodiment the counter electrode 213 may include a (semi)transparent layer that includes silver (Ag), magnesium (Mg), aluminum AL, platinum (Pt), palladium PD, gold (Au), nickel (Ni), neodymium (Nd), iridium (Ir), chromium (Cr), lithium (Li), calcium (Ca), or an alloy thereof. Alternatively, the counter electrode 213 may further include a layer, such as ITO, IZO, ZnO, or In2O3, arranged on the (semi)transparent layer including the aforementioned material.

In some embodiments, a capping layer may be further arranged on the counter electrode 213 (e.g., disposed directly thereon in the z direction). In an embodiment, the capping layer may include LiF, an inorganic material, or/and an organic material.

The thin-film encapsulation layer TFE may be arranged on the counter electrode 213. In an embodiment, the thin-film encapsulation layer TFE may include at least one inorganic encapsulation layer and at least one organic encapsulation layer. For example, the thin-film encapsulation layer TFE may include a first inorganic encapsulation layer 310, an organic encapsulation layer 320, and a second inorganic encapsulation layer 330 that are sequentially stacked (e.g., in the z-axis direction).

In an embodiment, the first inorganic encapsulation layer 310 and the second inorganic encapsulation layer 330 may include at least one inorganic material, selected from aluminum oxide, titanium oxide, tantalum oxide, hafnium oxide, zinc oxide, silicon oxide, silicon nitride, or silicon oxynitride. The organic encapsulation layer 320 may include a polymer-based material. The polymer-based material may include acrylic resin, epoxy resin, polyimide, and polyethylene. In an embodiment, the organic encapsulation layer 320 may include acrylate.

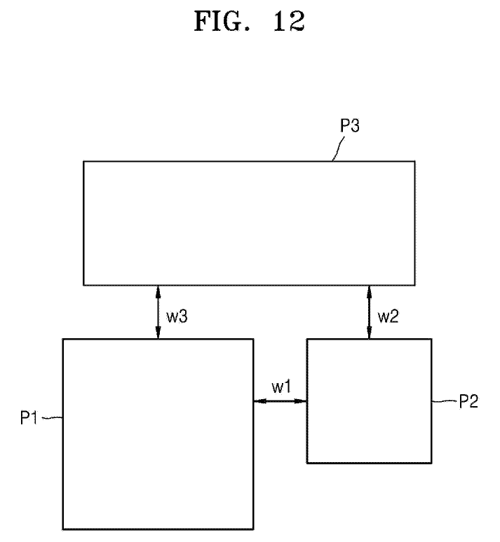

FIGS. 6 to 11 are schematic cross-sectional views of examples of a method of manufacturing a first pixel electrode, a second pixel electrode, and a third pixel electrode according to an embodiment, and FIG. 12 is a schematic plan view of an example of arranging a first sub-pixel, a second sub-pixel, and a third sub-pixel according to an embodiment.

First, referring to FIGS. 6 to 11 together with FIG. 5, the display device (1 of FIG. 1) according to an embodiment may include a substrate 100 including regions respectively corresponding to a first sub-pixel P1, a second sub-pixel P2, and a third sub-pixel P3, and a first pixel electrode 211a, a second pixel electrode 211b, and a third pixel electrode 211c arranged on the substrate 100 and located in the region corresponding to the first sub-pixel P1, the region corresponding to the second sub-pixel P2, and the region corresponding to the third sub-pixel P3, respectively.

In some embodiments, the first sub-pixel P1 may emit red light, the second sub-pixel P2 may emit blue light, and the third sub-pixel P3 may emit green light. However, embodiments of the present disclosure are not necessarily limited thereto and the respective colors emitted by the sub-pixels may vary. Each color of light, such as red, blue, and green light, may have a specific peak wavelength range. Accordingly, the first sub-pixel P1 emitting red light, the second sub-pixel P2 emitting blue light, and the third sub-pixel P3 emitting green light need to be implemented to have different resonance structures.

In case of a product including the existing large-size organic light-emitting diode OLEDs, a photolithography process performed a plurality of times has caused a limitation in implementing the first sub-pixel P1 emitting red light, the second sub-pixel P2 emitting blue light, and the third sub-pixel P3 emitting green light to have different resonance structures while having high resolution.

However, according to embodiments to be described below, even in case of a product including a large-size organic light-emitting diode OLED, the first sub-pixel P1, the second sub-pixel P2, and the third sub-pixel P3 may have different resonance structures while exhibiting increased resolution.

In some embodiments, referring to FIGS. 5 and 6, the first planarization layer 115 and the second planarization layer 116 that may each include the organic insulating layer may be arranged on the substrate 100, and the pixel electrode 211 may be arranged on the second planarization layer 116. However, embodiments of the present disclosure are not necessarily limited thereto, and in case that the second planarization layer 116 is omitted, the pixel electrode 211 may be arranged on the first planarization layer 115, and in case that another organic insulating layer is formed on the second planarization layer 116, the pixel electrode 211 may be arranged on the other organic insulating layer.

In an embodiment, the pixel electrode 211 may be formed from a metal laminate MA that is formed by sequentially stacking a first metal layer M1, a second metal layer M2, and a third metal layer M3 on the second planarization layer 116 (e.g., in the z direction). In an embodiment, the first metal layer M1, the second metal layer M2, and the third metal layer M3 may be formed continuously or individually.

In an embodiment, the first metal layer M1 and the third metal layer M3 may include conductive oxide. For example, in an embodiment the first metal layer M1 and the third metal layer M3 may each include at least one of indium tin oxide (ITO), indium zinc oxide (IZO), zinc oxide (ZnO), indium oxide (In2O3), indium gallium oxide (IGO), or aluminum zinc oxide (AZO).

The second metal layer M2 may include a reflective layer. For example, in an embodiment the second metal layer M2 may include at least one of silver (Ag), magnesium (Mg), aluminum (Al), platinum (Pt), palladium (Pd), gold (Au), nickel (Ni), neodymium (Nd), iridium (Ir), or chromium (Cr).

In some embodiments, the pixel electrode 211 may include a first pixel electrode 211a, a second pixel electrode 211b, and a third pixel electrode 211c. In an embodiment, the first pixel electrode 211a may be located in a region corresponding to the first sub-pixel P1 that emits red light, the second pixel electrode 211b may be located in a region corresponding to the second sub-pixel P2 that emits blue light, and the third pixel electrode 211c may be located in a region corresponding to the third sub-pixel P3 that emits green light. However, the number of the sub-pixels and the respective color that is emitted by each sub-pixel may vary.

A first photoresist pattern PR may be formed in the regions corresponding to the first sub-pixel P1 and the second sub-pixel P2 on the metal laminate MA that is formed by sequentially stacking the first metal layer M1, the second metal layer M2, and the third metal layer M3 on the second planarization layer 116.

As illustrated in FIG. 6, the first photoresist pattern PR located in the region corresponding to the first sub-pixel P1 may be thicker (e.g., in the z direction) than the first photoresist pattern PR located in the region corresponding to the second sub-pixel P2. In an embodiment, the first photoresist pattern PR may not be arranged in the region corresponding to the third sub-pixel P3.

In an embodiment, to form the first photoresist pattern PR, a mask pattern MK may be arranged in the region corresponding to the first sub-pixel P1, the second sub-pixel P2 and the third sub-pixel P3. For example, a binary photomask that shields light may be arranged in the region corresponding to the first sub-pixel P1, a halftone mask may be arranged in the region corresponding to the second sub-pixel P2, and a binary photomask through which light is transmitted may be arranged in the region corresponding to the third sub-pixel P3. In such embodiment, a photoresist used in the first photoresist pattern PR may be a positive photoresist.

However, embodiments of the present disclosure are not necessarily limited thereto, and various mask patterns may be used as long as a thickness of the first photoresist pattern PR located in the region corresponding to the first sub-pixel P1 is greater than the thickness of the first photoresist pattern PR located in the region corresponding to the second sub-pixel P2. For example, in an embodiment a halftone mask, an attenuated phase shift mask, or an alternating phase shift mask having a different light transmittance may be arranged on the regions corresponding to the first sub-pixel P1, the second sub-pixel P2, and the third sub-pixel P3. In an embodiment, a photoresist used in the first photoresist pattern PR may be a negative photoresist.

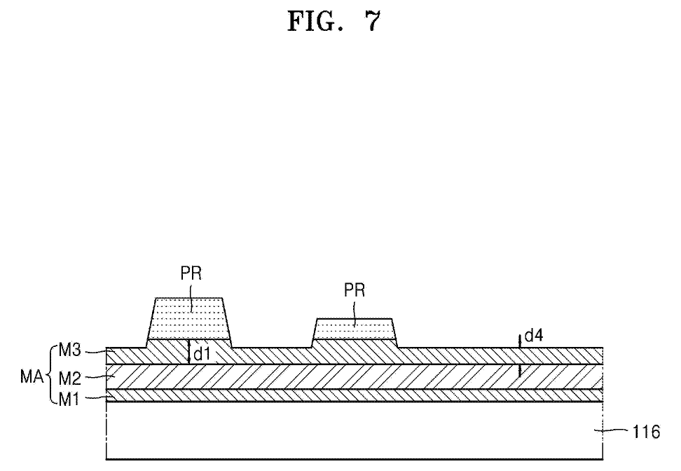

In some embodiments, referring to FIG. 7, after forming the first photoresist pattern PR on the metal laminate MA, a first etching process may be performed on the metal laminate MA. In an embodiment, the first etching process may be performed by dry etching or wet etching.

As described above, the first photoresist pattern PR may be arranged in the regions corresponding to the first sub-pixel P1 and the second sub-pixel P2, and may not be arranged in the region corresponding to the third sub-pixel P3. Therefore, the metal laminate MA in the regions corresponding to the first sub-pixel P1 and the second sub-pixel P2 may not be etched by the first etching process while being etched in the region corresponding to the third sub-pixel P3 by the first etching process.

However, the metal laminate MA in the regions corresponding to the first sub-pixel P1 and the second sub-pixel P2 not being etched does not necessarily mean that the metal laminate MA in the regions corresponding to the first sub-pixel P1 and the second sub-pixel P2 is not physically etched at all by the first etching process, but means that the metal laminate MA in the regions corresponding to the first sub-pixel P1 and the second sub-pixel P2 is not etched entirely by the first etching process, in contrast to the metal laminate MA in the region corresponding to the third sub-pixel P3. For example, in an embodiment in which the first etching process is performed by wet etching, the metal laminate MA in the regions corresponding to the first sub-pixel P1 and the second sub-pixel P2 may also be etched to some extent due to tolerance according to etching of a surrounding region.

In some embodiments, as illustrated in FIG. 7, during the first etching process of the metal laminate MA, the degree of etching may be adjusted so that the first metal layer M1 and the second metal layer M2 are not etched and only the third metal layer M3 is etched. In this embodiment, after the first etching process is performed a thickness d1 of the third metal layer M3 overlapping the first sub-pixel P1 (e.g., in the z direction) may be the same as a thickness of the third metal layer M3 (e.g., in the z direction) overlapping the second sub-pixel P2, and the thickness d1 of the third metal layer M3 overlapping the first sub-pixel P1 (e.g., in the z direction) may be greater than a thickness d4 of the third metal layer M3 overlapping the third sub-pixel P3.

For example, in an embodiment the thickness d1 of the third metal layers M3 that overlap the first sub-pixel P1 and the second sub-pixel P2 may be in a range of about 950 Å to about 1200 Å after the first etching process. The thickness d4 of the third metal layer M3 that overlaps the third sub-pixel P3 may be in a range of about 450 Å to about 650 Å after the first etching process.

In this specification, the 'thickness of the corresponding metal layer M1, M2, M3' means a length of the metal layer M1, M2, M3 that is measured along a third direction z (the “z direction”), which is a direction of stacking the components of the display device 1 described in FIG. 1. 'The thicknesses of the metal layers M1, M2, and M3 being the same' does not mean that the thicknesses of the metal layers M1, M2, and M3 are perfectly physically the same, and it may include errors due to tolerance.

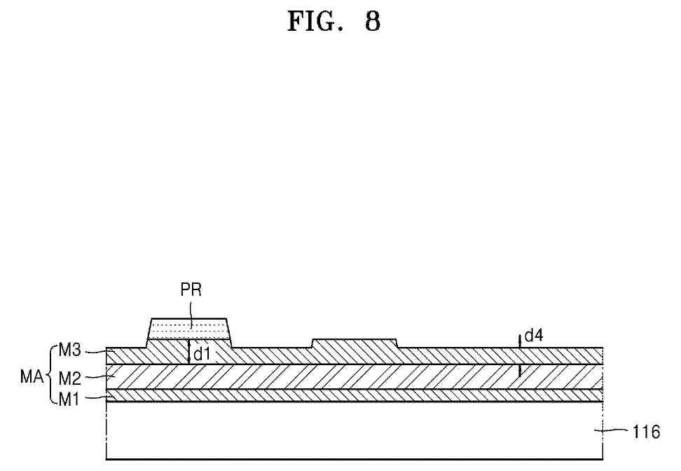

In some embodiments, referring to FIG. 8, after the first etching process of the metal laminate MA, the first photoresist pattern PR may be ashed. For example, the first photoresist pattern PR may be ashed without stripping so that the first photoresist pattern PR remains on the third metal layer M3 overlapping the first sub-pixel P1 as an ashed first photoresist pattern PR during a second etching process of the metal laminate MA to be described later.

In case of stripping the first photoresist pattern PR, the stripping may be performed in a wet manner using a chemical solution, so it may be difficult to control the first photoresist pattern PR to remain on the third metal layer M3 overlapping the first sub-pixel P1. In another example, in case of ashing the first photoresist pattern PR, the ashing may be performed in a dry manner using plasma or the like, so there may be an advantage in that it is easy to control the thickness of the first photoresist pattern PR.

As such, in case that the first photoresist pattern PR is ashed, the thickness of the first photoresist pattern PR in the region overlapping the first sub-pixel P1 may be reduced (e.g., decreased), and the first photoresist pattern PR in the region overlapping the second sub-pixel P2 may be removed.

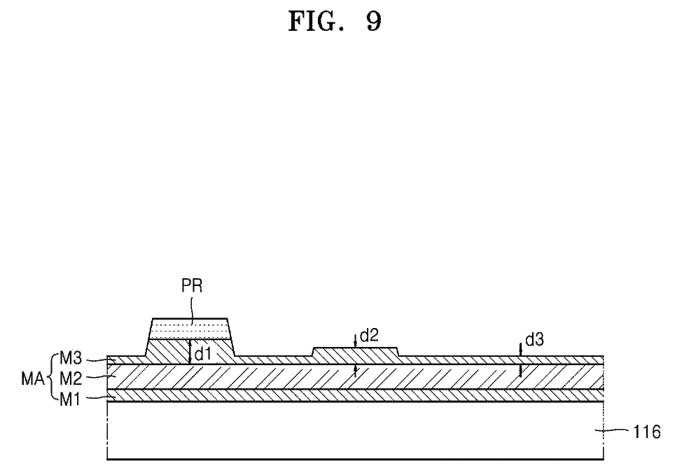

Referring to FIG. 9, after ashing the first photoresist pattern PR, the metal laminate MA etched by the first etching process may be etched by a second etching process using the ashed first photoresist pattern PR. In an embodiment, the second etching process may be performed by dry etching or wet etching.

The ashed first photoresist pattern PR may be arranged in the region corresponding to the first sub-pixel P1, and may not be arranged in the regions corresponding to the second sub-pixel P2 and the third sub-pixel P3. Therefore, the metal laminate MA in the region corresponding to the first sub-pixel P1 may not be etched while the metal laminate MA in the regions corresponding to the second sub-pixel P2 and the third sub-pixel P3 are etched.

However, that the metal laminate MA in the region corresponding to the first sub-pixel P1 is not etched does not mean that the metal laminate MA in the region corresponding to the first sub-pixel P1 is not physically etched at all, but means that the metal laminate P3 in the region corresponding to the first sub-pixel P1 is not etched entirely, in contrast to the metal laminate MA in the regions corresponding to the second sub-pixel P2 and the third sub-pixel P3. For example, in an embodiment in which the second etching process is performed by wet etching, the metal laminate MA in the region corresponding to the first sub-pixel P1 may also be etched to some extent due to tolerance according to etching of a surrounding region.

In some embodiments, as illustrated in FIG. 9, during the second etching process of the metal laminate MA, the degree of etching may be adjusted so that the first metal layer M1 and the second metal layer M2 are not etched and only the third metal layer M3 is etched. In this embodiment, the third metal layer M3 in the region corresponding to the second sub-pixel P2 may be etched, and the third metal layer M3 in the region corresponding to the third sub-pixel P3 may be further etched after the first etching process while the third metal layer M3 in the region corresponding to the first sub-pixel P1 is not etched during the second etching process due to the ashed first photoresist pattern PR.

Accordingly, a thickness d1 of the third metal layer M3 in the region corresponding to the first sub-pixel P1 may be greater than a thickness d2 of the third metal layer M3 in the region corresponding to the second sub-pixel P2, and the thickness d2 of the third metal layer M3 in the region corresponding to the second sub-pixel P2 may be thicker than a thickness d3 of the third metal layer M3 in the region corresponding to the third sub-pixel P3.

For example, in an embodiment the thickness d1 of the third metal layer M3 that overlaps the first sub-pixel P1 may be in a range of about 950 Å to about 1200 Å. The thickness d2 of the third metal layer M3 that overlaps the second sub-pixel P2 may be in a range of about 500 Å to about 750 Å. The thickness d3 of the third metal layer M3 that overlaps the third sub-pixel P3 may be in a range of about 50 Å to about 150 Å.

In this way, in the display device 1 according to embodiments, the third metal layers M3 of the first pixel electrode 211a of the first sub-pixel P1 emitting red light, the second pixel electrode 211b of the second sub-pixel P2 emitting blue light, and the third pixel electrode 211c of the third sub-pixel P3 emitting green light may be formed with different thicknesses from each other, so that a different resonance structure may be implemented for each sub-pixel P1, P2, and P3, thereby increasing light efficiency.

In some embodiments, as described above, during the ashing of the first photoresist pattern PR, the first photoresist pattern PR in the region overlapping the second sub-pixel P2 may be removed. Accordingly, a surface of the third metal layer M3 overlapping the second sub-pixel P2 may be damaged due to the ashing process. For example, the surface of the third metal layer M3 overlapping the second sub-pixel P2 may be damaged by plasma.

However, the third metal layer M3 overlapping the second sub-pixel P2 may be etched by the second etching process after the ashing process of the first photoresist pattern PR is performed, so that the surface of the third metal layer M3 overlapping the second sub-pixel P2, which has been damaged during the ashing process, may be removed. Accordingly, roughness of the surface of the third metal layer M3 overlapping the second sub-pixel P2 may be reduced, thereby increasing emission uniformity of the second sub-pixel P2.

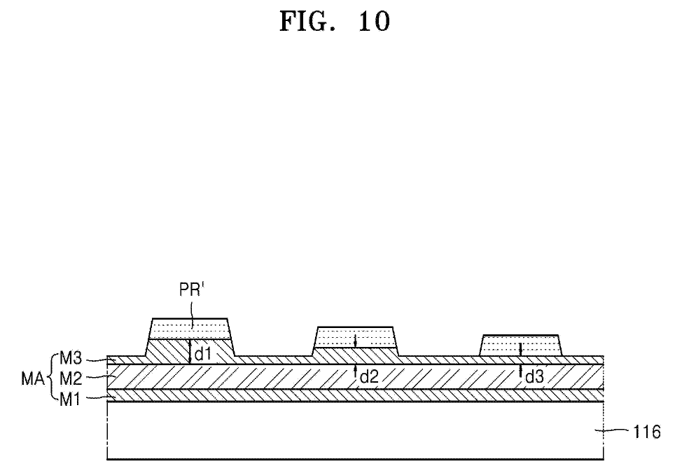

In the present disclosure, 'the surface of the third metal layer M3' may mean an upper surface of the third metal layer M3 or a surface, which is in direct contact with the photoresist pattern (PR of FIG. 9 or PR' of FIG. 10), among surfaces of the third metal layer M3. Likewise, 'a surface of the pixel electrode 211' may mean an upper surface of the pixel electrode 211 or a surface, which is in direct contact with the photoresist pattern PR or PR', among surfaces of the pixel electrode 211.

In the present disclosure, 'surface roughness' may be interpreted as a value that is obtained by measuring the change in height from a mean line in a surface profile. For example, a great surface roughness may mean that a surface is relatively unevenly bumpy, while a small surface roughness may mean that a surface is relatively even (e.g., planarized).

In some embodiments, referring to FIG. 10, after the second etching process of the metal laminate MA, the first photoresist pattern PR, such as the ashed first photoresist pattern PR, overlapping the first sub-pixel P1 may be removed (e.g., entirely removed) by a stripping or ashing process. Thereafter, a second photoresist pattern PR' may be formed in the regions corresponding to the first sub-pixel P1, the second sub-pixel P2, and the third sub-pixel P3.

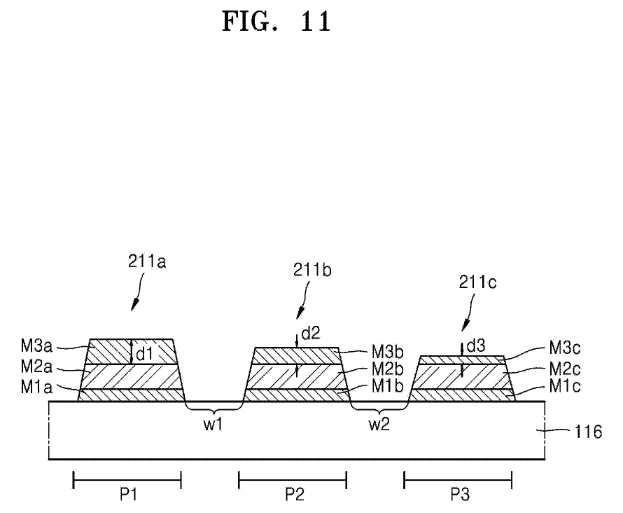

Thereafter, referring to FIG. 11, a third etching process may be performed for the metal laminate MA etched by the second etching process using the second photoresist pattern PR' as a mask, thereby forming the first pixel electrode 211a of the first sub-pixel P1, the second pixel electrode 211b of the second sub-pixel P2, and the third pixel electrode 211c of the third sub-pixel P3.

In an embodiment, the third etching process of the metal laminate MA may be performed by dry etching or wet etching. The third etching process of the metal laminate MA may be performed not only for the third metal layer M3, but also simultaneously for the first metal layer M1, the second metal layer M2, and the third metal layer M3. Thereafter, the second photoresist pattern PR' may be removed by ashing or stripping.

In some embodiments, the second photoresist pattern PR' may be formed in the regions corresponding to the first sub-pixel P1, the second sub-pixel P2, and the third sub-pixel P3, and accordingly the metal laminate MA in the regions corresponding to the first sub-pixel P1, the second sub-pixel P2, and the third sub-pixel P3 may not be etched. For example, the surface of the third metal layer M3a in the region corresponding to the first sub-pixel P1 may not be etched.

However, the metal laminate MA in the regions corresponding to the first sub-pixel P1, the second sub-pixel P2, and the third sub-pixel P3 not being etched may not mean that the metal laminate MA in the regions corresponding to the first sub-pixel P1, the second sub-pixel P2, and the third sub-pixel P3 is not physically etched at all, but may mean that the metal laminate MA is not etched entirely, in contrast to the metal laminate MA which is not masked with the second photoresist pattern PR'. For example, in an embodiment in which the third etching process is performed by wet etching, the metal laminate MA in the regions corresponding to the first sub-pixel P1, the second sub-pixel P2, and the third sub-pixel P3 may also be etched to some extent due to tolerance according to etching of a surrounding region.

In some embodiments, the first pixel electrode 211a located in the region corresponding to the first sub-pixel P1 may include a first metal layer M1a of the first pixel electrode 211a, a second metal layer M2a of the first pixel electrode 211a, and a third metal layer M3a of the first pixel electrode 211a that are formed from the metal laminate MA and sequentially stacked (e.g., in the z direction).

The second pixel electrode 211b located in the region corresponding to the second sub-pixel P2 may include a first metal layer M1b of the second pixel electrode 211b, a second metal layer M2b of the second pixel electrode 211b, and a third metal layer M3b of the second pixel electrode 211b that are formed from the metal laminate MA and sequentially stacked (e.g., in the z direction).

The third pixel electrode 211c located in the region corresponding to the third sub-pixel P3 may include a first metal layer M1c of the third pixel electrode 211c, a second metal layer M2c of the third pixel electrode 211c, and a third metal layer M3c of the third pixel electrode 211c that are formed from the metal laminate MA and sequentially stacked (e.g., in the z direction).

In some embodiments, as described above, the thickness of the first pixel electrode 211a (e.g., in the z direction) may be greater than the thickness of the second pixel electrode 211b (e.g., in the z direction), and the thickness (e.g., in the z direction) of the second pixel electrode 211b may be greater than the thickness of the third pixel electrode 211c (e.g., in the z direction). The respective thicknesses of the first to third pixel electrodes 211a, 211b, 211c may mean a total thickness (e.g., in the z direction) from the lowermost surface of the first metal layer to an uppermost surface of the third metal layer.

In this instance, the first metal layer M1a, M1b, M1c and the second metal layer M2a, M2b, M2c of each of the first pixel electrode 211a, the second pixel electrode 211b, and the third pixel electrode 211c may not be etched by being masked with the second photoresist pattern PR' during the third etching process of the metal laminate MA, so that the first metal layer M1a, M1b, M1c and the second metal layer M2a, M2b, M2c of each of the first pixel electrode 211a, the second pixel electrode 211b, and the third pixel electrode 211c may have the same thickness as each other (e.g., in the z direction).

The third metal layers M3a, M3b, and M3c of the first pixel electrode 211a, the second pixel electrode 211b, and the third pixel electrode 211c may have different thicknesses from each other (e.g., in the z direction). In some embodiments, a thickness d1 of the third metal layer M3a of the first pixel electrode 211a may be greater than a thickness d2 of the third metal layer M3b of the second pixel electrode 211b, and the thickness d2 of the third metal layer M3b of the second pixel electrode 211b may be greater than a thickness d3 of the third metal layer M3c of the third pixel electrode 211c.

For example, in an embodiment the thickness d1 of the third metal layer M3a of the first pixel electrode 211a may be in a range of about 950 Å to about 1200 Å. The thickness d2 of the third metal layer M3b of the second pixel electrode 211b may be in a range of about 500 Å to about 750 Å. The thickness d3 of the third metal layer M3c of the third pixel electrode 211c may be in a range of about 50 Å to about 150 Å.

In this way, in the display device 1 according to embodiments of the present disclosure, the third metal layers M3a, M3b, and M3c of the first pixel electrode 211a of the first sub-pixel P1 emitting red light, the second pixel electrode 211b of the second sub-pixel P2 emitting blue light, and the third pixel electrode 211c of the third sub-pixel P3 emitting green light may have different thicknesses from each other, so that a different resonance structure may be implemented for each sub-pixel P1, P2, and P3, thereby increasing light efficiency.

In some embodiments, as described above, the third metal layer M3a of the first pixel electrode 211a located in the region corresponding to the first sub-pixel P1 may be masked with the first photomask pattern PR during the first and second etching processes of the metal laminate MA, and may be masked with the second photomask pattern PR' during the third etching process of the metal laminate MA. For example, the third metal layer M3a of the first pixel electrode 211a located in the region corresponding to the first sub-pixel P1 may not be etched during each of the first etching process, the second etching process, and the third etching process. Accordingly, an increase in surface roughness of the third metal layer M3a of the first pixel electrode 211a due to the etching processes may be minimized, thereby increasing emission uniformity of the first pixel electrode 211a.

In some examples, the third metal layer M3b of the second pixel electrode 211b located in the region corresponding to the second sub-pixel P2 may be etched during the second etching process of the metal laminate MA, and the third metal layer M3c of the third pixel electrode 211c located in the region corresponding to the third sub-pixel P3 may be etched during the first and second etching processes of the metal laminate MA. Accordingly, the surface roughness of the third metal layer M3a of the first pixel electrode 211a may be less than the surface roughness of the third metal layers M3b and M3c of the second pixel electrode 211b and the third pixel electrode 211c.

In some embodiments, in the display device the first metal layer M1 and the second metal layer M2 may be etched once during the third etching process of the metal laminate MA, such that separation distances between adjacent pixel electrodes of the first pixel electrode 211a, the second pixel electrode 211b, and the third pixel electrode 211c may be minimized. For example, unlike the present disclosure, in a comparative case that the first metal layer M1 and the second metal layer M2 are etched at least twice instead of being etched once, the tolerance may also cumulatively increase as the number of etching processes increases. This may cause an increase in the separation distances between the adjacent pixel electrodes of the first pixel electrode 211a, the second pixel electrode 211b, and the third pixel electrode 211c.

However, as illustrated in embodiments of the present disclosure, in case that the first metal layer M1 and the second metal layer M2 are etched only once during the third etching process of the metal laminate MA, the tolerance may be minimized, so that the separation distances between the adjacent pixel electrodes of the first pixel electrode 211a, the second pixel electrode 211b, and the third pixel electrode 211c may be minimized, and the separation distances between the adjacent pixel electrodes of the first pixel electrode 211a, the second pixel electrode 211b, and the third pixel electrode 211c may be made the same. In case that the first metal layer M1 and the second metal layer M2 are etched a plurality of times, the tolerance may accumulate, which may cause a limitation in manufacturing the display device 1 in a manner that the separation distances between the adjacent pixel electrodes of the first pixel electrode 211a, the second pixel electrode 211b, and the third pixel electrode 211c are minimized, and the separation distances between the adjacent pixel electrodes of the first pixel electrode 211a, the second pixel electrode 211b, and the third pixel electrode 211c are made the same.

For example, according to embodiments, as illustrated in FIGS. 11 and 12, a separation distance w1 (e.g., a first separation distance) between the first pixel electrode 211a and the second pixel electrode 211b (e.g., in a plan view) and a separation distance w2 (e.g., a second separation distance) between the second pixel electrode 211b and the third pixel electrode 211c (e.g., in a plan view) may be the same as each other. The separation distance w2 between the second pixel electrode 211b and the third pixel electrode 211c (e.g., in a plan view) and a separation distance w3 (e.g., a third separation distance) between the third pixel electrode 211c and the first pixel electrode 211a (e.g., in a plan view) may be the same as each other.

As described above, the separation distances between the adjacent pixel electrodes of the first pixel electrode 211a, the second pixel electrode 211b, and the third pixel electrode 211c may be minimized. For example, in an embodiment the separation distance w1 between the first pixel electrode 211a and the second pixel electrode 211b, the separation distance w2 between the second pixel electrode 211b and the third pixel electrode 211c, and the separation distance w3 between the third pixel electrode 211c and the first pixel electrode 211a may be in a range of about 7 μm to about 10 μm.

In case that the separation distances between the adjacent pixel electrodes of the first pixel electrode 211a, the second pixel electrode 211b, and the third pixel electrode 211c are the same in the range, resolution, color uniformity, and image clarity of the display device 1 and an electronic device including the same may be increased.

Here, 'the separation distances between the adjacent pixel electrodes of the first pixel electrode 211a, the second pixel electrode 211b, and the third pixel electrode 211c being the same' may not mean that the separation distances between the adjacent pixel electrodes of the first pixel electrode 211a, the second pixel electrode 211b, and the third pixel electrode 211c are perfectly physically the same (e.g., identical to each other), and it may be of course that there may be some deviation due to tolerance errors.

In some embodiments, in case of manufacturing the first pixel electrode 211a, the second pixel electrode 211b, and the third pixel electrode 211c according to embodiments, as can be seen from the manufacturing process described above, the first metal layer M1 and the second metal layer M2 may be etched only once during the third etching process of the metal laminate MA. Accordingly, a photolithography process may be performed without exposing the second metal layer M2 to an external environment.

For example, in an embodiment the second metal layer M2 includes silver (Ag). In case that the second metal layer M2 is exposed to an external environment before a photolithography process, unlike embodiments of the present disclosure, silver oxide (Ag2O) may be generated, which may deteriorate the reflective characteristics of the second metal layer M2. However, according to embodiments of the present disclosure, the second metal layer M2 may not be exposed to the external environment before the photolithography process, and thus there may be no concern that silver (Ag) is oxidized to generate silver oxide (Ag2O), thereby increasing the optical characteristics of the display device 1 and an electronic device including the same.

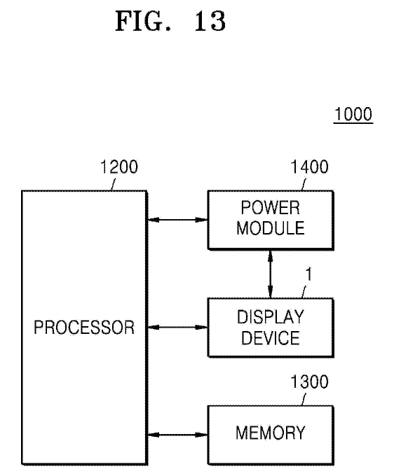

FIG. 13 is a block diagram of an electronic device according to an embodiment.

Referring to FIG. 13, an electronic device 1000 according to an embodiment may include a display device 1, a processor 1200, a memory 1300, and a power module 1400.

The display device 1 may receive data from the processor 1200 and provide visual information. The display device 1 may be the display device 1 according to embodiments described above.

In a embodiment, the processor 1200 may include at least one of a central processing unit (CPU), an application processor (AP), a graphic processing unit (GPU), a communication processor (CP), an image signal processor (ISP), or a controller. For example, the processor 1200 may operate by executing at least one program.

The memory 1500 may store data information that is necessary for the operation of the processor 1200 or the display device 1. For example, the memory 1500 may store the at least one program. In case that the processor 1200 executes an application stored in the memory 1500, an image data signal and/or an input control signal may be transmitted to the display device 1, and the display device 1 may process the received signal and output image information through a display screen.

In an embodiment, the power module 1400 may include a power supply module, such as a power adapter or a battery device, and a power conversion module that converts power supplied by the power supply module to generate power required for the operation of the electronic device 1000. For example, the power module 1400 may supply power to the display device 1.

At least one of the components of the electronic device 1000 may be included in the display device 1 according to the foregoing embodiments. Some of individual modules functionally included in a single module may be included in the display device 1 and others may be provided separately from the display device 1.

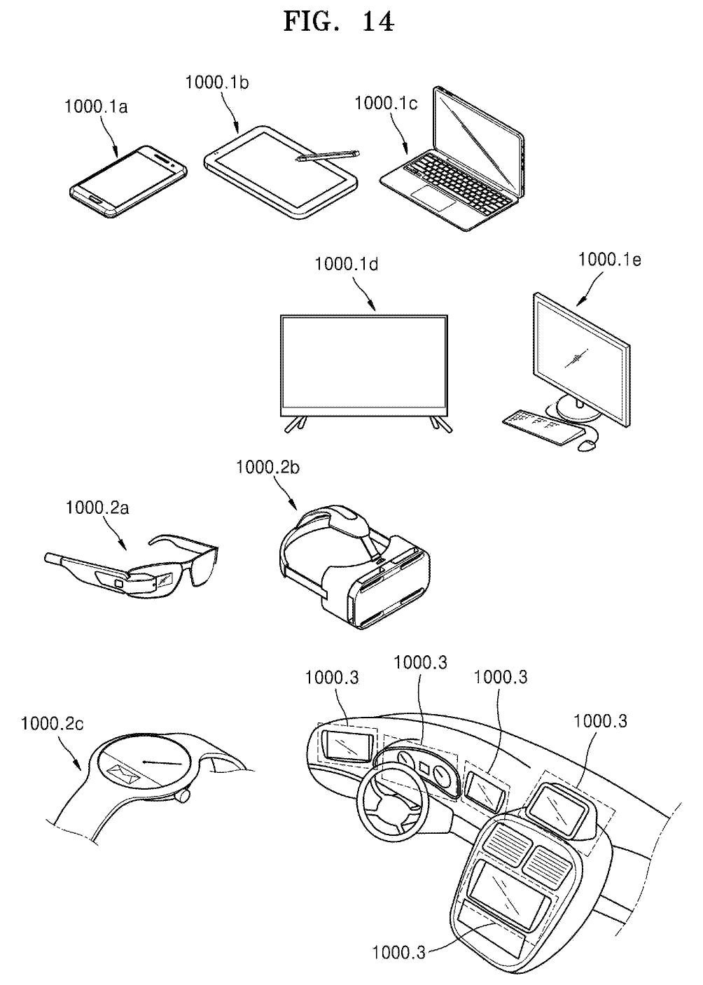

FIG. 14 is a variety of schematic diagrams of electronic devices according to various embodiments.

Referring to FIG. 14, various electronic devices to which the display device according to embodiments is applied may include image display electronic devices, such as a smart phone 1000.1a, a tablet PC 1000.1b, a laptop 1000.1c, a TV 1000.1d, and a desk monitor 1000.1e, wearable electronic devices including display devices, such as smart glasses 1000.2a, a head mounted display 1000.2b, and a smart watch 1000.2c, and vehicle electronic devices 1000.3 including display devices, such as a center information display (CID) arranged on a dashboard, center fascia, and dashboard of an automobile, and a room mirror display.

According to one or more embodiments, third metal layers of a first pixel electrode, a second pixel electrode, and a third pixel electrode may be made to have different thicknesses from each other, so that a different resonance structure is implemented for each sub-pixel of an organic light-emitting diode, thereby increasing light efficiency.

By minimizing etching of a surface of a first pixel electrode, surface roughness of the first pixel electrode may be reduced, resulting in an increase in emission uniformity of the first pixel electrode.

In case of forming a first pixel electrode, a second pixel electrode, and a third pixel electrode, an etching process may be performed once for each of a first metal layer and a second metal layer, so that a separation distance between the first pixel electrode and the second pixel electrode and a separation distance between the second pixel electrode and the third pixel electrode may be the same. This may increase resolution, color uniformity, and image clarity of a display device and an electronic device including the same.

However, the effects obtainable through embodiments of the present disclosure are not limited to the effects described above, and other technical effects not mentioned will be clearly understood by those skilled in the art from the description of embodiments of the present disclosure described above.

Each of the described embodiments may be implemented independently, but of course, the structure of each embodiment may be applied in combination to other embodiments.

As such, the present disclosure has been described with reference to non-limiting embodiments illustrated in the drawings, but is merely illustrative, and it will be understood by those skilled in the art that various modifications and variations of the embodiments may be made.

The executions specified in the described embodiments are merely illustrative, and do not limit the scope of the present disclosure in any way.

In the specification, the use of the term ʺtheʺ and similar referential terms may refer to both the singular and the plural.

In case that a range is specified in the described embodiments, it includes the invention to which individual values within the range are applied (unless otherwise indicated herein). This is the same as stating each individual value constituting the above range in the detailed description.

Finally, unless an order of steps constituting the method according to the present disclosure is explicitly described or a reverse order is not mentioned, those steps may be carried out in any suitable order. The embodiments are not necessarily limited by the order of steps described above.

The use of any examples or illustrative terms in the described embodiments is merely to describe the present disclosure in detail.

Further, it will be understood by those skilled in the art that various modifications, combinations and changes may be made depending on design conditions and factors.

What is claimed is:

1. A method of manufacturing a display device, the method comprising: forming a metal laminate by sequentially stacking a first metal layer, a second metal layer, and a third metal layer on a substrate, the metal laminate including regions corresponding to a first sub-pixel, a second sub-pixel and a third sub-pixel;
forming a first photoresist pattern in the regions corresponding to the first sub-pixel and the second sub-pixel and then performing a first etching process on the metal laminate, wherein the first photoresist pattern is not formed in the region corresponding to the third sub-pixel;
ashing the first photoresist pattern after performing the first etching process to form an ashed first photoresist pattern;
performing, using the ashed first photoresist pattern, a second etching process on the metal laminate which has been etched by the first etching process;
forming a first pixel electrode of the first sub-pixel, a second pixel electrode of the second sub-pixel, and a third pixel electrode of a third sub-pixel by removing the ashed first photoresist pattern; and
forming a second photoresist pattern in the region corresponding to the first sub-pixel, the region corresponding to the second sub-pixel, and a region corresponding to the third sub-pixel, and performing a third etching process on the metal laminate which has been etched by the second etching process,
wherein the first pixel electrode, the second pixel electrode, and the third pixel electrode are formed to have different thicknesses from each other.

2. The method of claim 1, wherein:
the thickness of the first pixel electrode is greater than the thickness of the second pixel electrode; and
the thickness of the second pixel electrode is greater than the thickness of the third pixel electrode.

3. The method of claim 1, wherein:
a first separation distance between the first pixel electrode and the second pixel electrode is equal to a second separation distance between the second pixel electrode and the third pixel electrode; and
a third separation distance between the third pixel electrode and the first pixel electrode is equal to the first and second separation distances.

4. The method of claim 1, wherein:
a thickness of the first photoresist pattern in the region corresponding to the first sub-pixel is greater than a thickness of the first photoresist pattern in the region corresponding to the second sub-pixel.

5. The method of claim 1, wherein:
the third metal layers of the first pixel electrode, the second pixel electrode, and the third pixel electrode have different thicknesses from each other.

6. The method of claim 5, wherein:
the first metal layer and the second metal layer of each of the first pixel electrode, the second pixel electrode, and the third pixel electrode have a same thickness as each other.

7. The method of claim 1, wherein:
during the first etching process of the metal laminate,
the third metal layer in the region corresponding to the third sub-pixel is etched.

8. The method of claim 7, wherein:
after the first etching process of the metal laminate is performed, a thickness of the third metal layer overlapping the first sub-pixel is equal to a thickness of the third metal layer overlapping the second sub-pixel.

9. The method of claim 8, wherein:
after the first etching process of the metal laminate is performed, the thickness of the third metal layer overlapping the first sub-pixel is greater than a thickness of the third metal layer overlapping the third sub-pixel.

10. The method of claim 7, wherein:
during the ashing of the first photoresist pattern,
a thickness of the first photoresist pattern in the region overlapping the first sub-pixel decreases; and
the first photoresist pattern in the region overlapping the second sub-pixel is removed.

11. The method of claim 10, wherein:
during the second etching process of the metal laminate, the third metal layer in the region corresponding to the third sub-pixel is further etched.

12. The method of claim 11, wherein:
after the second etching process of the metal laminate is performed, a thickness of the third metal layer in the region corresponding to the second sub-pixel is greater than a thickness of the third metal layer in the region corresponding to the third sub-pixel.

13. The method of claim 1, wherein:
the third etching process of the metal laminate is performed by wet etching.

14. The method of claim 13, wherein:
a surface of the third metal layer in the region corresponding to the first sub-pixel is not etched during the first to third etching processes.

15. The method of claim 1, wherein
the first sub-pixel emits red light, the second sub-pixel emits blue light, and the third sub-pixel emits green light.

16. A display device comprising:
a substrate comprising regions corresponding to a first sub-pixel, a second sub-pixel, and a third sub-pixel, respectively; and
a first pixel electrode, a second pixel electrode, and a third pixel electrode arranged on the substrate, and located in the region corresponding to the first sub-pixel, the region corresponding to the second sub-pixel, and the region corresponding to the third sub-pixel, respectively,
wherein the first pixel electrode, the second pixel electrode, and the third pixel electrode each comprise a first metal layer, a second metal layer, and a third metal layer sequentially stacked,
the third metal layers of the first pixel electrode, the second pixel electrode, and the third pixel electrode have different thicknesses from each other, and
a roughness of a surface of the third metal layer of the first pixel electrode is less than a roughness of a surface of the third metal layer of the second pixel electrode.

17. The display device of claim 16, wherein:
a first separation distance between the first pixel electrode and the second pixel electrode is equal to a second separation distance between the second pixel electrode and the third pixel electrode; and
a third separation distance between the third pixel electrode and the first pixel electrode is equal to the first and second separation distances.

18. The display device of claim 16, wherein:
the thickness of the third metal layer of the first pixel electrode is greater than the thickness of the third metal layer of the second pixel electrode; and
the thickness of the third metal layer of the second pixel electrode is greater than the thickness of the third metal layer of the third pixel electrode.

19. The display device of claim 16, wherein:
the first sub-pixel emits red light, the second sub-pixel emits blue light, and the third sub-pixel emits green light.

20. An electronic device comprising:
a memory in which at least one program is stored;
a processor configured to operate by executing the at least one program;
a display device configured to provide visual information by receiving data from the processor; and
a power module configured to supply power to the display device,
wherein the display device comprises:
a substrate comprising regions corresponding to a first sub-pixel, a second sub-pixel, and a third sub-pixel, respectively; and
a first pixel electrode, a second pixel electrode, and a third pixel electrode arranged on the substrate, and located in the region corresponding to the first sub-pixel, the region corresponding to the second sub-pixel, and the region corresponding to the third sub-pixel, respectively,
the first pixel electrode, the second pixel electrode, and the third pixel electrode each comprise a first metal layer, a second metal layer, and a third metal layer sequentially stacked,
the third metal layers of the first pixel electrode, the second pixel electrode, and the third pixel electrode have different thicknesses from each other, and
a roughness of a surface of the third metal layer of the first pixel electrode is less than a roughness of a surface of the third metal layer of the second pixel electrode.
